(19) United States
(12) Patent Application Publication
(10) Pub. No.: US 2008/0142071 A1
(43) Pub. Date: Jun. 19, 2008

(54) Protovoltaic module utilizing a flex circuit for reconfiguration

(75) Inventors: Randy Dorn, Santa Clara, CA (US); Bruce Hachtmann, San Martin, CA (US); David Harris, Carpinteria, CA (US); Ilan Gur, San Francisco, CA (US); David Pearce, Saratoga, CA (US); William Sanders, Mountain View, CA (US); Ben Tarbell, Palo Alto, CA (US)

Correspondence Address: FOLEY AND LARDNER LLP;SUITE 500, 3000 K STREET NW, WASHINGTON, DC, 20007, US

(73) Assignee: Miasole

(21) Appl. No.: 11/639,428

(22) Filed: Dec. 15, 2006

(51) Int. Cl. H01L 31/045; H01L 31/042

(52) U.S. Cl. 136/245; 136/244

(57) ABSTRACT

A photovoltaic (PV) module includes a plurality of PV cells and a plurality of reconfigurable interconnects which electrically interconnect the plurality of PV cells.

### FIELD OF THE INVENTION

The present invention relates generally to a photovoltaic device and more particularly to reconfigurable photovoltaic modules.

### BACKGROUND

Most of the photovoltaic (PV) modules (which are also known as solar cell modules) are passive devices that are configured with a fixed arrangement of PV cells (which are also known as solar cells), interconnections and output characteristics. In the vast majority of these module products, the cell to cell interconnections are made using a tab and string method by soldering copper strips between adjacent cells.

The prior art module products have many limitations relating to their manufacture, installation and operation. These include the complexity of forming the interconnection and configuring multiple products for multiple customer demands; the performance degradation from shading, hotspots, and low light; and the complexity of installing modules in a variety of locations each with characteristic constraints on the placement of modules.

### SUMMARY

An embodiment of the invention provides a PV module, comprising a plurality of PV cells and a plurality of reconfigurable interconnects which electrically interconnect the plurality of PV cells.

### BRIEF DESCRIPTION OF THE DRAWINGS

FIGS. 1A-1F are circuit schematics of a flexible circuit according to the embodiments of the invention.

FIG. 2A is a top view of an interconnect according to an embodiment of the invention.

FIGS. 2B, 2D and 2E are side cross sectional views of an interconnect according to an embodiment of the invention.

FIG. 2C is a three dimensional view of an interconnect according to an embodiment of the invention.

FIG. 3A is a top view of an insulating sheet according to an embodiment of the invention.

FIG. 3B is a side cross sectional view of a module containing the insulating sheet according to an embodiment of the invention.

FIGS. 4A, 4G and 4H are three dimensional views of a module according to an embodiment of the invention.

FIGS. 4B, 4J and 4K are side views of modules according to embodiments of the invention.

FIGS. 4C-4F, 4I and 5A-5B are top views of modules according to an embodiment of the invention.

FIG. 6 is cut away, side view of interconnected modules according to an embodiment of the invention.

### DETAILED DESCRIPTION

The embodiments of the invention provide improved manufacture, installation, and operation of photovoltaic modules utilizing an integrated and internal flexible circuit. The circuit serves as a means of collection of current from PV cells and as the electrical interconnection of two or more PV cells for the purpose of transferring the current generated in one PV cell to adjacent cells and/or out of the PV module to the output connectors.

A PV module includes a plurality of PV cells and a plurality of reconfigurable interconnects which electrically interconnect the plurality of PV cells. In the first embodiment, the plurality of interconnects comprise a reconfigurable circuit which in operation collects current from the plurality of PV cells. The interconnection between the plurality of PV cells may be reconfigured after fabrication of the PV module is completed. For example, the reconfiguration may take place after an insulating laminating material is formed over the cells to complete the module and/or after the initial interconnection of the cells is completed.

The interconnection between the cells in the module may be reconfigured to optimize one or more of the following properties. For example, the interconnection may be reconfigured to optimize at least one of module output current, voltage, frequency and/or power. Alternatively, the interconnection can be reconfigured to maximize module output power by accommodating underperforming or overperforming PV cells or isolating non-functioning PV cells. For example, the interconnection can be optimized to maximize power by accommodating hotspots, damaged, shaded, or otherwise underperforming cells, by isolating these underperforming cells from the other cells and/or from the output leads (which may also be referred to as output contacts, connectors or terminals). Alternatively, cells that are performing better than others in its string may be connected to a different string and/or connected separately to the output leads. Alternatively, the interconnection can be reconfigured such that the output characteristics of the module are made to more efficiently match inverter requirements across varied light conditions. Such a module could also divert power to one or more secondary paths, such as providing some power to charge a battery and the remaining power to an inverter as a function of the environment. Cell connectivity could also be modified to disconnect all cells as a safety feature.

As used herein, the term “module” includes an assembly of at least two, and preferably three or more, such as 3 to 10,000 electrically interconnected PV cells. Each PV cell includes a photovoltaic material, such as a semiconductor material. For example, the photovoltaic semiconductor material may comprise a p-n or p-i-n junction in a Group IV semiconductor material, such as amorphous or crystalline silicon, a Group II-VI semiconductor material, such as CdTe or CdS, a Group I-III-VI semiconductor material, such as CuInSe₂ (CIS) or Cu(In,Ga)Se₂ (CIGS), and/or a Group III-V semiconductor material, such as GaAs or InGaP. The p-n junctions may comprise heterojunctions of different materials, such as a CIGS/CdS heterojunction, for example. Each cell also contains front and back side electrodes. These electrodes can be designated as first and second polarity electrodes since electrodes have an opposite polarity. For example, the front side electrode may be electrically connected to an n-side of a p-n junction and the back side electrode may be electrically connected to a p-side of a p-n junction. The front side electrode on the front surface of the cells may be an optically transparent electrode which is adapted to face the Sun, and may comprise a transparent conductive material, such as indium tin oxide or aluminum doped zinc oxide. The back side electrode on the back surface of the cells is adapted to face away from the Sun, and may comprise one or more conductive materials, such as copper, molybdenum, aluminum, stainless steel and/or alloys thereof. If the module is formed on an electrically conductive substrate, such as a flexible stainless steel sheet or other material, then the back side electrode may be electrically connected to the substrate. For example, the module formed on a flexible substrate may comprise a mechanically flexible, large area module.

The module also contains the interconnects that form a grid-like contact to the cell electrodes, such as the front side electrodes. The interconnect may include thin traces or gridlines as well as optional thick bus bars or bus lines, as will be described in more detail below. If bus bars or bus lines are present, then the gridlines may be arranged as thin “fingers” which extend from the bus bars or bus lines. The interconnects may be formed directly over the front side electrodes of the cells. Alternatively, the interconnects may be first formed on an insulating carrier sheet, which is then attached to the exposed front side electrodes of the cells, as described in more detail in U.S. application Ser. No. 11/451,604, filed on Jun. 13, 2006 and incorporated herein by reference in its entirety.

The module may also include an optional detector, which in operation, monitors performance of the plurality of the PV cells. The detector may comprise a photodetector array which is dispersed throughout the module and which monitors the light conditions in different portions of the module. Alternatively, the detector may comprise one or more voltmeters or ammeters which measure voltage or current, respectively, at different cells in the module.

Modules with active, automatic reconfigurations of the interconnections may also include a control device, such as a computer, an operator control panel, a microcontroller, a logic chip or a logic circuit. The control device controls reconfiguration of the interconnection between the plurality of PV cells based on information provided by the detector regarding performance of the plurality of PV cells. Thus, the control device may be electrically connected to the detector and automatically reconfigure the interconnection of the cells. Alternatively, for a control panel type control device, a human operator operates the control panel based on observed information displayed or otherwise provided by the detector.

In one aspect of the first embodiment, the reconfiguration discussed above can be made actively such that the interconnections can be automatically reconfigured by switching devices. Non-limiting examples of such switching devices include electromechanical or mechanical switches, transistors or other solid state devices, such as fuses and/or antifuses, relays or other devices for making or breaking electrical contact. The switching devices electrically connect or disconnect the plurality of PV cells to or from each other. The switching devices can also electrically connect or disconnect the plurality of PV cells to or from one or more interconnects, such as conductive bus lines or traces. The switching devices may be switched manually or automatically by the control device.

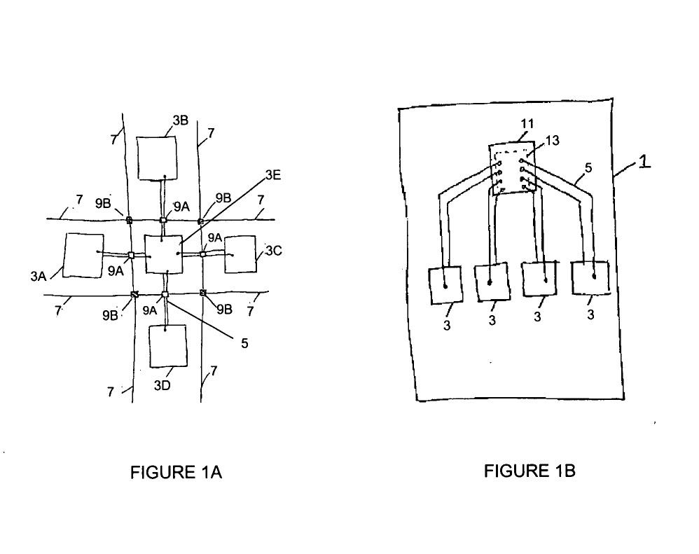

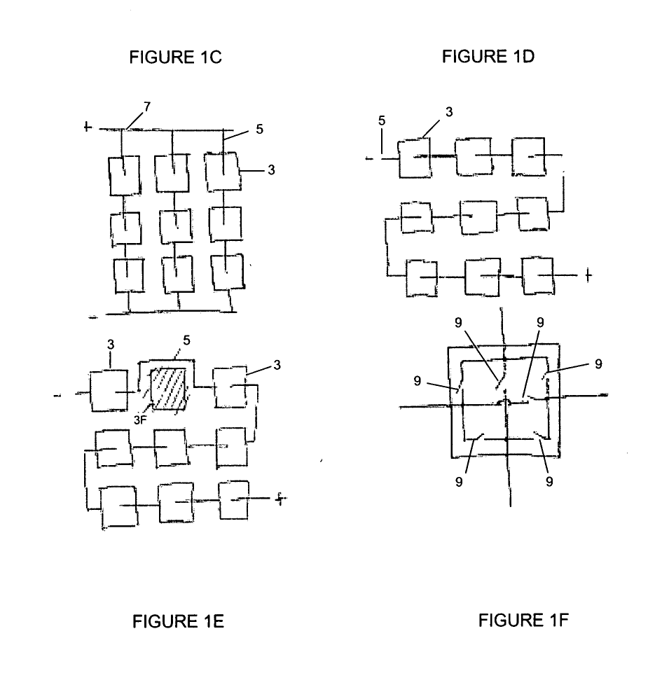

FIG. 1A illustrates a circuit schematic of a module containing the switching devices. The module 1 contains a plurality of cells 3A, 3B, 3C, 3D and 3E interconnected by traces 5 and bus lines 7. The switching devices 9A can be distributed within the module placed at each interconnection node between one cell 3E and its adjacent cells 3A-3D such that both polarities of each cell 3E are connected to the switches 9A between each adjacent cell. The switches 9A are also connected to common bus lines 7. The bus lines are connected to each other by switches 9B. Switches 9A and 9B may be the same or different types of switches. Each PV cell can be interconnected directly in series or parallel through the bus lines 7 with its adjacent cells, and subsequently connected through switches to the two output leads of the module.

In another aspect of the first embodiment shown in FIG. 1B, similar flexibility could be achieved by connecting both polarities of each PV cell 3 in the module 1 by conductive traces 5 to a common connection point in the junction box 11. The module interconnections could then be configured using an integrated circuit 13 that selectively connects the cells in the optimum configuration. This integrated circuit 13 (and/or other ancillary or external sensors and logic described above) monitor the performance of the module or individual cells and optimize the interconnection configuration. The software algorithms that perform this optimization may reside on the module (i.e., run on an embedded controller, control chip or circuit) or could be external to the module (i.e., run on an external computer or other controller). In addition, the cells may be configured such that a shaded cell could act as a bypass diode.

FIGS. 1C-1E illustrate examples of reconfigured interconnections in a flexible circuit. For example, the circuit of FIG. 1A is reconfigured into three strings of cells connected in parallel, as shown in FIG. 1C. The cells in each string are connected in series. Alternatively, the circuit may be reconfigured to connect all cells in series, as shown in FIG. 1D. In case one cell 3F shown in FIG. 1E becomes underperforming or non-performing, such as by being shaded or damaged, it is isolated from the other cells in the modules and current is routed around this cell. FIG. 1F illustrates the location of similar switching devices 9, such that every trace or lead can be connected to every other lead that connects to the switch. The reconfiguration of the interconnection of the cells may occur in the factory or in the field after the completion of the manufacture of the module.

In the second and third embodiments of the invention, the interconnections can be optimized or customized in a fixed configuration in the factory or in the field. This may be done by selectively making a connection or a series of connections between the traces or bus lines on the circuit, or by breaking a connection or series of connections in the traces or bus line in the circuit. The interconnects can configured so that they remain fixed in that configuration for the life of the module. Alternatively, the interconnects can be reconfigured multiple times throughout the life of the module.

In the second embodiment, instead of using switching devices, such as electromechanical switches, transistors, or relays of the first embodiment, conductive bridges are placed between the traces or bus lines to reconfigure the interconnections. Alternatively, individual traces (or in some cases individual bus lines) may be selectively broken to reconfigure the interconnections.

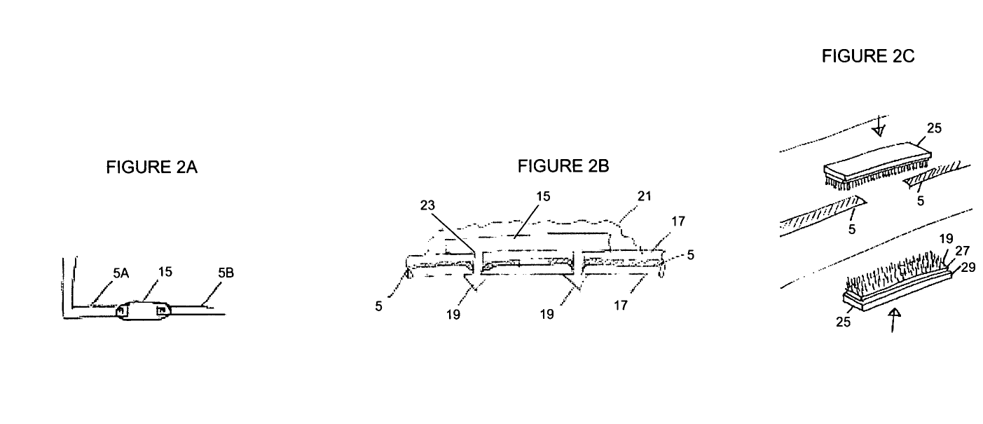

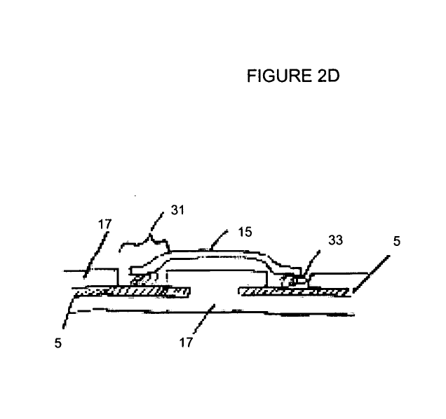

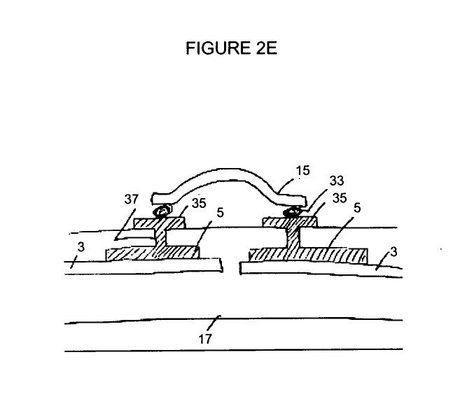

As shown in FIG. 2A, the selective connections between the cells, traces and/or bus lines are made with a physical conductive bridge 15. For example, as shown in FIG. 2A, the bridge 15 forms an electrical interconnect between two adjacent, unconnected traces 5A and 5B. Any suitable conductive material, such as copper, aluminum, their alloys, etc. may be used as the bridge material.

As shown in FIG. 2B, the conductive bridge 15 can be formed between two adjacent traces after a module has been laminated with an electrically insulating laminating material 17 over the plurality of PV cells. The bridge 15 is formed by piercing the laminate and traces 5 with conductive barbs 19 which protrude from the bottom of the bridge 15. The barbs make intimate electrical contact with the traces 5. After the connection with the barbed bridge is made, a sealant 21, such as silicone, is formed over the bridge 15 to maintain the integrity of the laminate. Thus, the conductive bridge 15 contains at least a portion which is located over the laminating material 17. The bridge interconnects at least two PV cells through one or more openings 23 in the laminating material 17. Any suitable insulating material may be used as the laminating material, such as thermal plastic olefin (TPO), EVA, PET or other polymers.

In an alternative configuration shown in FIG. 2C, the interconnection is made with intersecting and conducting barbed pads 25 that puncture each side of the laminate and the traces 5 forming an electrical connection. The barbed pads contain a conductive layer 27, a sealing layer 29 and a matrix of conductive barbs 19.

Alternatively, as shown in FIG. 2D, traces 5 can be selectively connected by selectively removing sections 31 of the laminating layer 17 to expose the conductive traces 5 underneath. Once the conductive traces 5 are exposed, a conductive bridge 15 can be attached using various of interconnection methods known in the art to make a connection, including but not limited to soldering, spot welding, crimping and using conductive adhesives 33.

In another configuration shown in FIG. 2E, vias or openings 37 are formed in the laminating layer 17 over adjacent traces 5. Then pads 35 are formed in the vias 37 such that the pads are exposed in or over the surface of the laminating layer 17. The pads 35 may be formed by selective electroless plating or electroplating on the traces 5 or by any other suitable deposition method. The pads may be formed of any metal that may be plated, such as copper, nickel, their alloys, etc. Adjacent traces 5 are then interconnected by attaching the conductive bridge 15 to adjacent pads 35. An additional layer of laminating or sealing material may be placed on top of the bridge after the interconnection has been completed. It should be noted that while the bridges 15 are preferably connected to traces 5, the bridges may be connected to the bus lines 7 or directly to cell 3 electrodes if desired.

In an alternative configuration, the conductive bridges 15 discussed above may be replaced by other connectors, such as screw terminals, mini junction boxes, or universal connectors, which are used to connect the traces to each other. The universal connectors may be used for interconnection within the module, interconnection between modules, or ports for test probes in the factory or in the field.

In a third embodiment, the module comprises at least one interconnect containing a break formed after the fabrication of the module is completed. As used herein, a break means a discontinuity in the interconnect such that the interconnect cannot conduct current across the discontinuity. For example, the traces 5 can be selectively broken by punching, slicing, slitting, or cutting through the trace and laminating layer and then adding a sealant or additional layers of protective laminating material to preserve the integrity of the laminated module. The traces may be broken by mechanical means, such as a hole punch, drill or a saw, or by ultrasonic or optical means, such as by a focused ultrasonic or laser cutting instrument, for example.

The traces could also be selectively broken by pumping sufficient current to destroy the trace selectively in the area where the trace should be removed. In other words, the traces 5 act as antifuses which are blown by passing a current above a critical current through the selected traces. In addition, traces may selectively broken by stretching, tearing, or deforming the trace where the connection should be broken.

In addition, the shorting of underperforming cells through the flexible configuration may be a planned part of the module manufacturing process to simplify or eliminate the cell sorting process allowing the planned removal of the worst performing cells in each module.

In a fourth embodiment, the modules are customized during manufacturing, such as at a factory, by using a custom trace layout for each module. This mass customization may be achieved by utilizing flexible printing methods, such as ink-jet printing, to define the layout of conductive traces. Customers could order their desired configuration from a list of feasible configurations in a catalog or on a website.

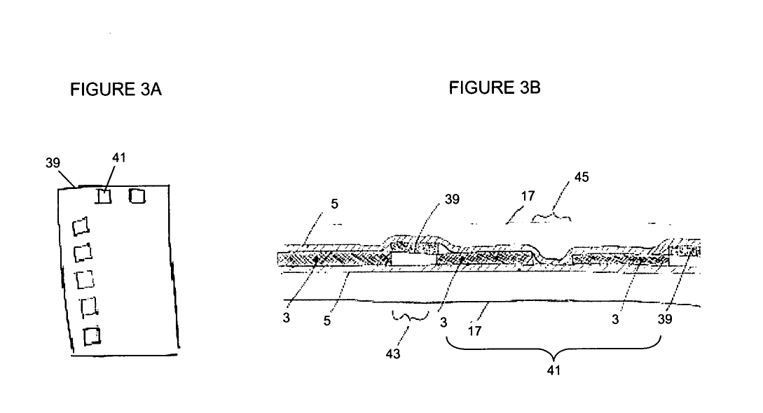

In another aspect of the fourth embodiment, a custom interconnect configuration is achieved in the factory by selectively placing an insulating layer or sheet between two layers of mating material that contain the conductive traces 5. As shown in FIG. 3A, the insulating layer 39 comprises a thin, transparent film that is selectively punched with windows or openings 41. As shown in FIG. 3B, the mating traces 5 from opposite sides of adjacent PV cells 3 electrically contact each other through the openings 41 from opposite sides of the module in region 45 between adjacent cells 3, to form the interconnection. In region 43 where the insulating layer 39 remains, no interconnection between traces 5 is made. The module of this embodiment is formed by forming the back side electrodes (which include back side traces) 5 over a substrate and forming the PV cells 3 over the back side electrodes. Each PV cell 3 electrically contacts one of the back side electrodes 5. The insulating sheet 39 with the openings 41 is then formed over the of PV cells 3. The PV cells 3 and portions of some but not all of the back side electrodes 5 are exposed in the openings 41. A front side electrode layer (such as a trace layer) 5 is formed over the insulating sheet 39. The front side electrode layer electrically contacts the PV cells 3 and portions of those back side electrodes which are exposed in the openings 41.

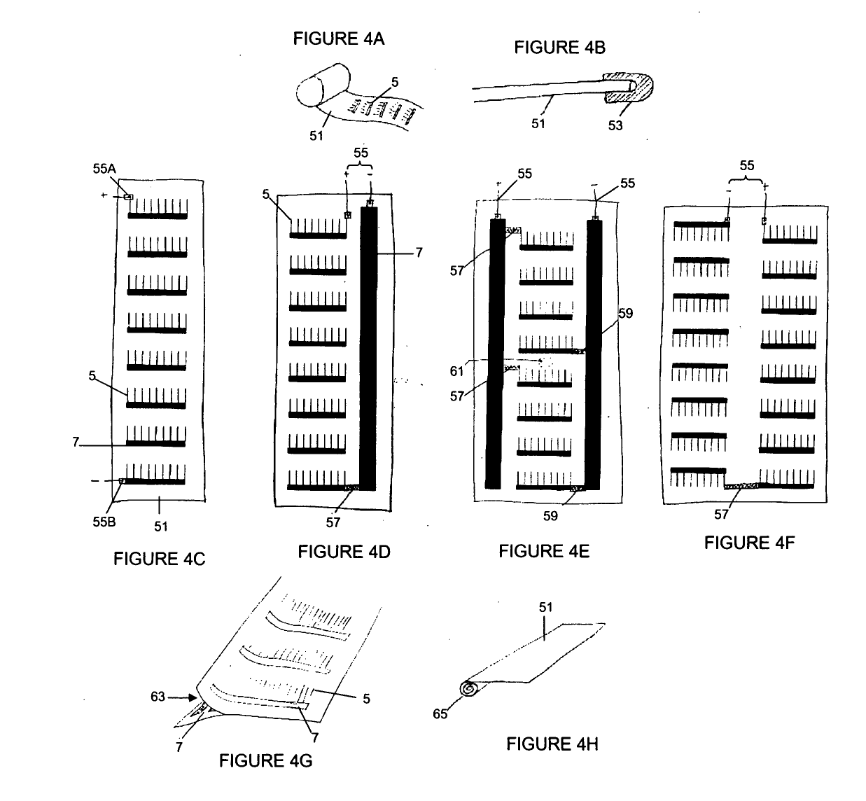

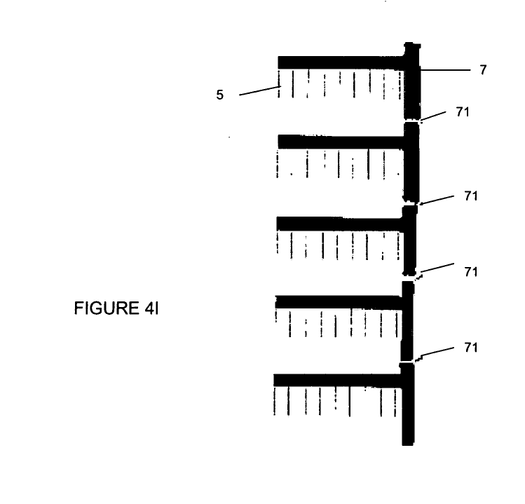

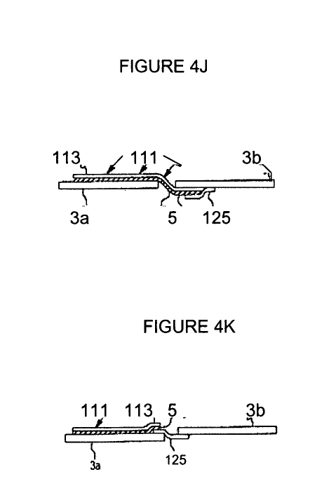

In a fifth embodiment, the modules are separated from a continuous sheet or roll (i.e., a rolled up sheet) of strings of cells. The modules are made by providing a sheet (such as a rolled up or unrolled sheet) of repeating, interconnected PV cells. One or more PV modules are separated from the sheet. The module is configured to have a plurality of output locations, as will be discussed in more detail below. The output leads or a junction box are then attached in some but not all of the plurality of output locations, such as the desired output locations based on the module installation location, to allow more freedom during the installation of the module. A shown in FIG. 4A, the cells and traces 5 are formed as mechanically flexible thin film devices on a flexible substrate, such as a metal or polymer sheet, which is rolled up into a roll 51. An installer in the field can then cut a desired length of the photovoltaic module material from the continuous roll 51. Where the roll 51 is cut, a secondary sealing layer, 53 such as silicone or epoxy, may be added in the field by the installer, as shown in FIG. 4B. The roll 51 may be cut between each cell, across a cell, or at increments of several cells. If desired, perforations may be added periodically along the roll to enable the installer to more easily separate the desired length of cell string by simply tearing across the perforations. The strings could be limited to the number of cells that produce the maximum voltage (for example 600V) allowed by certifying bodies such as UL.

Once the desired length of string is cut or torn, the cell interconnections and final electrical termination can be made. For example, in a simplest case shown in FIG. 4C, the output leads 55A and 55B are connected to opposing polarities at opposite ends of the string of cells (i.e., at the opposite ends of the module) which are connected by traces 5 and bus lines 7. Each row of traces 5 in FIG. 4C is electrically connected to an adjacent row through the PV cells (not shown for clarity) to complete the circuit.

If desired, both output leads 55 are placed on the same end of the string (i.e., the same end of the module) by connecting one of the polarities (i.e., the bottom set of traces) with an interconnect 57 to a bus line 7 that runs the length of the module, as shown in FIG. 4D. Thus, one of the output leads is connected to this bus line 7 while the other lead is connected to the upper set of traces. The terms bottom and upper are relative terms used to explain the illustration in the Figures, and should not be presumed to require the leads to be located on a particular side of an installed module.

In an alternative configuration shown in FIG. 4E, the module contains two bus lines 7 which run along the length of the module. Multiple strings are connected in parallel by connecting the same polarity of each string to one of the bus lines by bridges or interconnects 57 while connecting the opposing polarity to the other bus line using bridges or interconnects 59. The output leads 55 are then attached to the bus lines 7 at the same end of the module. The electrical connection between the strings is removed in location 61 by breaking the connecting trace or electrode by one of the methods described above.

Alternatively, as shown in FIG. 4F, the module may contain multiple opposing strings (such as two strings for example) but no bus line which runs the length of the module. Both output leads or connectors 55 are placed on the same side of the module. The two strings are interconnected at the opposite side of the module by bridge or interconnect 57.

If desired, the laminated module may contain at least one open edge 63, as shown in FIG. 4G. In other words, the top and bottom laminating material of the module is not sealed on one or more edges to expose the conductive traces or bus lines. This enables the installer to access the traces or bus lines to place the output leads in electrical contact with the traces or bus lines to complete the interconnections. After the interconnection has been completed, the edge can be sealed in the field using a portable laminating tool. The seal of the edge may be improved by rolling or folding the edge over as shown in FIG. 4H to form a rolled edge 65.

In another embodiment shown in FIG. 4I, bypass diodes 71 are connected to connecting to traces 5 or bus lines 7 on the flexible circuit at appropriate places in the string of PV cells. For example, a diode 71 is attached at each point shown in FIG. 41 where there is a break in the traces or bus lines connecting adjacent cells. This would provide a bypass diode for each cell. If fewer diodes are desired, then multiple cells are bypassed by one diode using a similar method, where the trace connects both ends of the string with a break for the diode. The diode can come in a variety of packages, including a surface mount IC or a cylindrical IC with metallic leads and can be attached using methods common in the art, including soldering and conductive adhesives.

In another embodiment, the interconnection is part of a collector-connector described in U.S. patent application Ser. No. 11/451,616, filed on Jun. 13, 2006, which is incorporated herein by reference in its entirety. The “collector-connector” is a device that acts as both a current collector to collect current from at least one photovoltaic cell of the module, and as an interconnect which electrically interconnects the at least one photovoltaic cell with at least one other photovoltaic cell of the module. In general, the collector-connector takes the current collected from each cell of the module and combines it to provide a useful current and voltage at the output connectors of the module. This collector-connector 111 (which can also be referred to as a “decal”) preferably comprises an electrically insulating carrier 113 and at least one electrical conductor 5 which electrically connects one photovoltaic cell 3a to at least one other photovoltaic cell 3b of the module, as shown in FIGS. 4J and 4K.

The collector-connector 111 electrically contacts the first polarity electrode of the first photovoltaic cell 3a in such a way as to collect current from the first photovoltaic cell. For example, the electrical conductor 5 electrically contacts a major portion of a surface of the first polarity electrode of the first photovoltaic cell 3a to collect current from cell 3a. The conductor 5 portion of the collector-connector 111 also directly or indirectly electrically contacts the second polarity electrode of the second photovoltaic cell 3b to electrically connect the first polarity electrode of the first photovoltaic cell 3a to the second polarity electrode of the second photovoltaic cell 3b.

Preferably, the carrier 113 comprises a flexible, electrically insulating polymer film having a sheet or ribbon shape, supporting at least one electrical conductor 5. Examples of suitable polymer materials include thermal polymer olefin (TPO). TPO includes any olefins which have thermoplastic properties, such as polyethylene, polypropylene, polybutylene, etc. Other polymer materials which are not significantly degraded by sunlight, such as EVA, other non-olefin thermoplastic polymers, such as fluoropolymers, acrylics or silicones, as well as multilayer laminates and co-extrusions, such as PET/EVA laminates or co-extrusions, may also be used. The insulating carrier 113 may also comprise any other electrically insulating material, such as glass or ceramic materials. The carrier 113 may be a sheet or ribbon which is unrolled from a roll or spool and which is used to support conductor(s) 5 which interconnect three or more cells 3 in a module. The carrier 113 may also have other suitable shapes besides sheet or ribbon shape.

The conductor 5 may comprise any electrically conductive trace or wire. Preferably, the conductor 5 is applied to an insulating carrier 113 which acts as a substrate during deposition of the conductor. The collector-connector 111 is then applied in contact with the cells 3 such that the conductor 5 contacts one or more electrodes of the cells 3. For example, the conductor 5 may comprise a trace, such as silver paste, for example a polymer-silver powder mixture paste, which is spread, such as screen printed, onto the carrier 113 to form a plurality of conductive traces on the carrier 113. The conductor 5 may also comprise a multilayer trace. For example, the multilayer trace may comprise a seed layer and a plated layer. The seed layer may comprise any conductive material, such as a silver filled ink or a carbon filled ink which is printed on the carrier 113 in a desired pattern. The seed layer may be formed by high speed printing, such as rotary screen printing, flat bed printing, rotary gravure printing, etc. The plated layer may comprise any conductive material which can by formed by plating, such as copper, nickel, cobalt or their alloys. The plated layer may be formed by electroplating by selectively forming the plated layer on the seed layer which is used as one of the electrodes in a plating bath. Alternatively, the plated layer may be formed by electroless plating. Alternatively, the conductor 5 may comprise a plurality of metal wires, such as copper, aluminum, and/or their alloy wires, which are supported by or attached to the carrier 113.

FIGS. 4J and 4K illustrate modules in which the carrier film 113 contains conductive traces 5 printed on one side. The traces 5 electrically contact the active surface of cell 3a (i.e., the front electrode of cell 3a) collecting current generated on that cell 3a. A conductive interstitial material may be added between the conductive trace 5 and the cell 3a to improve the conduction and/or to stabilize the interface to environmental or thermal stresses. The interconnection to the second cell 3b is completed by a conductive tab 125 which contacts both the conductive trace 5 and the back side of cell 3b (i.e., the back side electrode of cell 3b). The tab 125 may be continuous across the width of the cells or may comprise intermittent tabs connected to matching conductors on the cells. The electrical connection can be made with conductive interstitial material, conductive adhesive, solder, or by forcing the tab material 125 into direct intimate contact with the cell or conductive trace. Embossing the tab material 125 may improve the connection at this interface. In the configuration shown in FIG. 4J, the collector-connector 111 extends over the back side of the cell 3b and the tab 125 is located over the back side of cell 3b to make an electrical contact between the trace 5 and the back side electrode of cell 3b. In the configuration of FIG. 4K, the collector-connector 111 is located over the front side of the cell 3a and the tab 125 extends from the front side of cell 3a to the back side of cell 3b to electrically connect the trace 5 to the back side electrode of cell 3b.

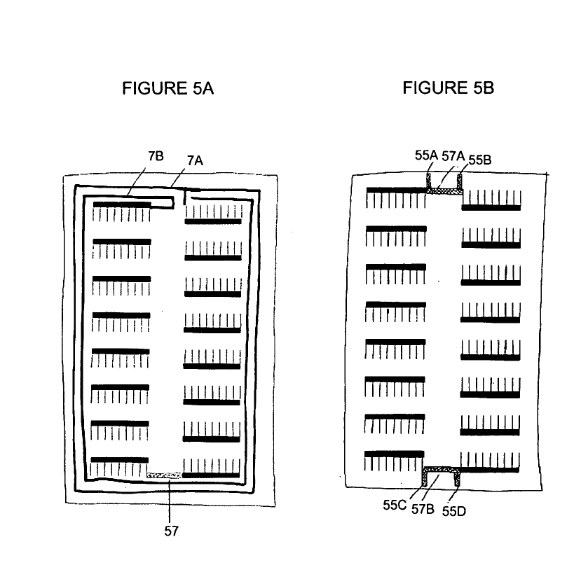

In another embodiment, the location of the junction box or output leads on the module can be customized in the field using the interconnection techniques described above. As shown in FIG. 5A, the module contains a first conductive bus line 7A and a second conductive bus line 7B of opposite polarity, both of which extend around a periphery of the module. The junction box or output leads can be located in electrical contact with the conductive bus lines 7A, 7B at any desired or predetermined peripheral location of the module. In other words, by placing buses of each polarity around the perimeter of the module, the installer has the freedom to put the junction box or output leads anywhere around the perimeter of the module.

In another configuration shown in FIG. 5B, the module contains two sets of electrically conductive traces and two interconnects or conductive bridges 57A, 57B connecting the two sets of traces at different locations. One of the bridges is broken (i.e., cut, etc.) and a junction box or output leads are placed in contact with the two sets of traces at the location of the break. For example, if interconnect 57A is broken, then the output leads 55A, 55B are placed in contact with the traces around the broken bridge 57A. If interconnect 57B is broken, then the output leads 55C, 55D are placed in contact with the traces around the broken bridge 57B. Thus, the leads (or the junction box) can be placed on either side of the module depending on which interconnect is broken. In addition, by removing both interconnects 57A, 57B, the module will contain two independent strings are connected at opposite ends of the module.

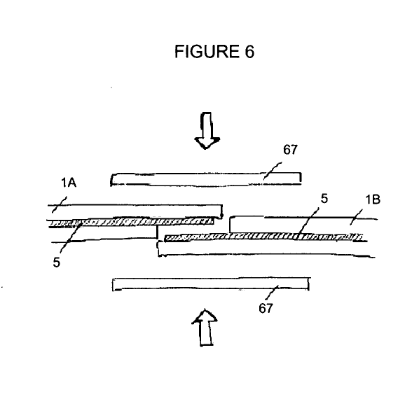

In a sixth embodiment, the conductive traces can be used to make interconnections between modules rather than within a single module. For example, as shown in FIG. 6, sections of trace material 5 are exposed at the edge of each module 1A, 1B. The exposed trace section in each module faces in the opposite direction from that in the adjacent module. The interconnection between these modules is formed by lapping (i.e., overlapping) the adjacent modules such that the exposed sections of the trace material contact each other. An adhesive or other sealing material 67 is then provided on both sides of the interconnection region to seal the joint.

Thus, in summary, the reconfigurable flexible circuit enables multiple configurations of interconnection between the cells, as well as multiple configurations of current and voltage flow and output. The reconfigurable module is less expensive, more durable, and allows more light to strike the active area of the photovoltaic module. In addition, a reconfigurable module provides additional value, flexibility and cost savings to the manufacturers, installers, and users of PV modules.

Although the foregoing refers to particular preferred embodiments, it will be understood that the present invention is not so limited. It will occur to those of ordinary skill in the art that various modifications may be made to the disclosed embodiments and that such modifications are intended to be within the scope of the present invention. All of the publications, patent applications and patents cited herein are incorporated herein by reference in their entirety.

1. A photovoltaic (PV) module, comprising:
a plurality of PV cells; and
a plurality of reconfigurable interconnects which electrically interconnect the plurality of PV cells.

2. The module of claim 1, wherein the module comprises a mechanically flexible, large area module.

3. The module of claim 1, wherein the plurality of interconnects comprise a reconfigurable circuit which in operation collects current from the plurality of PV cells.

4. The module of claim 3, wherein in operation, the interconnection is reconfigured between the plurality of PV cells to optimize at least one of module output current, voltage, frequency or power.

5. The module of claim 3, wherein in operation, the interconnection is reconfigured between the plurality of PV cells to maximize module output power by accommodating underperforming or overperforming PV cells or isolating non-functioning PV cells.

6. The module of claim 3, wherein in operation, the interconnection is reconfigured between the plurality of PV cells to match inverter requirements across varied light conditions.

7. The module of claim 3, further comprising:
a detector, which in operation, monitors performance of the plurality of the PV cells; and
a control device, which in operation, controls reconfiguration of the interconnection between the plurality of PV cells based on information provided by the detector regarding performance of the plurality of PV cells.

8. The module of claim 3, wherein the circuit comprises a plurality of switching elements which in operation electrically connect or disconnect the plurality of PV cells to or from each other, or which electrically connect or disconnect the plurality of PV cells to or from one or more interconnects.

9. The module of claim 3, further comprising:
an electrically insulating laminating material located over the plurality of PV cells; and
at least one conductive bridge containing at least a portion which is located over the laminating material and which interconnects at least two PV cells through one or more openings in the laminating material.

10. The module of claim 3, wherein the circuit comprises at least one screw terminal, mini-junction box or universal connector which in operation reconfigures the interconnection between the plurality of PV cells.

11. The module of claim 3, wherein the circuit comprises at least one interconnect containing a break formed after the module is completed.

12. The module of claim 3, further comprising an insulating sheet containing a predetermined configuration of openings, such that mating conductive traces from opposite sides of adjacent PV cells contact each other through the openings.

13. The module of claim 1, further comprising:
a first conductive bus line and a second conductive bus line of opposite polarity to the first conductive bus line, wherein the first and the second conductive bus lines extended around a periphery of the module; and
a junction box or output leads located in electrical contact with the first and the second conductive bus lines at a predetermined peripheral location of the module.

14. The module of claim 1, further comprising:
a first set of electrically conductive traces;
a second set of electrically conductive traces;
a first electrically conductive bridge connecting the first and the second sets of traces at a first location;
a second electrically conductive bridge containing a break positioned at a second location different from the first location; and
a junction box or output leads located in electrical contact with the first and the second set of traces at the second location.

15. The module of claim 1, further comprising a collector-connector which comprises an electrically insulating carrier and the plurality of flexible interconnects formed on the insulating carrier, wherein the collector-connector is configured to collect current from a first photovoltaic cell and to electrically connect the first photovoltaic cell with a second photovoltaic cell.

16. The module of claim 1, further comprising a plurality of bypass diodes located in breaks in the plurality of flexible interconnects.

17. A method of making a PV module, comprising:
providing a sheet of repeating, interconnected PV cells;
separating a PV module from the sheet, wherein the module is configured to have a plurality of output locations; and
attaching output leads or a junction box in some but not all of the plurality of output locations.

18. A method of operating a PV module comprising a plurality of PV cells and a plurality interconnects which electrically interconnect the plurality of PV cells, the method comprising reconfiguring interconnection between the plurality of PV cells after fabrication of the PV module is completed.

19. The method of claim 18, wherein the interconnection between the plurality of PV cells is reconfigured to at least one of:
(a) optimize at least one of module output current, voltage, frequency or power;
(b) maximize module output power by accommodating underperforming or overperforming PV cells or isolating non-functioning PV cells; or
(c) match inverter requirements across varied light conditions.

20. The method of claim 18, further comprising:
monitoring performance of the plurality of the PV cells; and
controlling the reconfiguration of the interconnection between the plurality of PV cells based on the performance of the plurality of PV cells.

21. The method of claim 18, wherein the step of reconfiguring comprises operating at least one switching device to electrically connect or disconnect the plurality of PV cells to or from each other, or to electrically connect or disconnect the plurality of PV cells to or from one or more bus lines.

22. The method of claim 18, wherein the step of reconfiguring comprises:
forming at least one opening in an electrically insulating laminating material located over the plurality of PV cells; and
forming least one conductive bridge over the laminating material to interconnect at least two PV cells through the at least one opening in the laminating material.

23. The method of claim 18, wherein the step of reconfiguring comprises electrically, optically or mechanically forming at least one break in at least one interconnect.

24. The method of claim 18, further comprising:
providing the module containing a first conductive bus line and a second conductive bus line of opposite polarity to the first conductive bus line, wherein the first and the second conductive bus lines extended around a periphery of the module; and
placing a junction box or output leads in electrical contact with the first and the second conductive bus lines at a desired peripheral location of the module.

25. The method of claim 18, further comprising:
providing the module comprising a first set of electrically conductive traces,
a second set of electrically conductive traces, a first electrically conductive bridge connecting the first and the second sets of traces at a first location, and a second electrically conductive bridge positioned at a second location different from the first location;
breaking the second bridge; and
placing junction box or output leads located in electrical contact with the first and the second set of traces at the second location.

26. The method of claim 18, wherein the step of reconfiguring comprises permanently reconfiguring the interconnection.

27. The method of claim 18, further comprising reversibly reconfiguring the interconnection between the plurality of PV cells a plurality of times.

28. A method of making a PV module, comprising:
forming a plurality of back side electrodes over a substrate;
forming a plurality of PV cells, wherein each PV cell electrically contacts a respective one of the plurality of back side electrodes;
forming a predetermined configuration of openings in an insulating sheet based on desired module interconnect characteristics;
placing the insulating sheet over the plurality of PV cells, such that the plurality of PV cells and portions of some of the plurality of the back side electrodes are exposed in the openings; and
forming a front side electrode layer over the insulating sheet, such that the front side electrode layer electrically contacts the plurality of PV cells and portions of some of the plurality of the back side electrodes exposed in the openings.

29. A PV module, comprising:
a plurality of PV cells;
a plurality interconnects which electrically interconnect the plurality of PV cells; and
a first means for reconfiguring interconnection between the plurality of PV cells after fabrication of the PV module is completed.

30. The module of claim 29, wherein the first means reconfigures the interconnection between the plurality of PV cells to at least one of:
(a) optimize at least one of module output current, voltage, frequency or power;
(b) maximize module output power by accommodating underperforming or overperforming PV cells or isolating non-functioning PV cells; or
(c) match inverter requirements across varied light conditions.

31. The module of claim 29, further comprising:
a second means for monitoring performance of the plurality of the PV cells; and
a third means for controlling the reconfiguration of the interconnection between the plurality of PV cells by the first means based on information provided by the second means regarding performance of the plurality of PV cells.
